(19) United States
(12) Patent Application Publication
(10) Pub. No.: US 2025/0283222 A1
(43) Pub. Date: Sep. 11, 2025

(54) FILM FORMING DEVICE AND METHOD FOR FORMING CARBON FILM

(71) Applicant: Resonac Hard Disk Corporation, Chiba (JP)

(72) Inventor: Yasuhiro MORI, Yamagata (JP)

(21) Appl. No.: 19/065,266

(22) Filed: Feb. 27, 2025

(30) Foreign Application Priority Data
Mar. 5, 2024 (JP) 2024-033062

(51) Int. Cl. C23C 16/48; C23C 16/26; C23C 16/458

(52) U.S. Cl. CPC C23C 16/486; C23C 16/26; C23C 16/4582

(57) ABSTRACT

A film forming device includes: a film forming chamber; a holder configured to hold a substrate in the film forming chamber; an inlet pipe configured to introduce a gas of a raw material containing carbon into the film forming chamber; a cathode electrode that is filamentous; a first power source configured to heat the cathode electrode by energization; an anode electrode provided around the cathode electrode; a second power source configured to generate a discharge between the cathode electrode and the anode electrode; a third power source configured to generate a potential difference between the cathode electrode or the anode electrode and the substrate; an ionization area configured to ionize the gas to generate an ionized gas by the discharge; and an acceleration area in which the ionized gas is accelerated by the potential difference. A soft-magnetic cylinder is provided around the acceleration area.

### CROSS-REFERENCE TO RELATED APPLICATIONS

The present application is based on and claims priority to Japanese Patent Application No. 2024-033062 filed on Mar. 5, 2024, the entire contents of which are hereby incorporated by reference.

### BACKGROUND

### 1. Field of the Invention

The present disclosure relates to a film forming device and a method for forming a carbon film.

### 2. Description of the Related Art

In recent years, in the field of magnetic recording media used for hard disk drives (HDDs) and the like, enhancement of recording density has been demanded. There are various technologies to support such enhancement of recording density. One of them is to shorten a distance between a magnetic head and a magnetic layer of a magnetic recording medium.

Here, a protective film is interposed between the magnetic layer of the magnetic recording medium and the magnetic head, which is an issue in reducing the distance between the magnetic head and the magnetic layer. In order to increase the recording density of the magnetic recording medium by shortening the distance between the magnetic head and the magnetic layer, it is necessary to enhance smoothness of the protective film and reduce thickness of the protective film.

For example, Japanese Laid-Open Patent Application No. 2011-65714 discloses a carbon-film forming device in which the distance between the magnetic recording medium and the magnetic head can be shortened by stabilizing the thickness distribution of the carbon film used as the protective film of the magnetic recording medium.

### SUMMARY

The present disclosure includes the following:

[1] A film forming device, comprising:
a film forming chamber;
a holder configured to hold a substrate in the film forming chamber;
an inlet pipe configured to introduce a gas of a raw material containing carbon into the film forming chamber;
a cathode electrode that is filamentous;
a first power source configured to heat the cathode electrode by energization;
an anode electrode provided around the cathode electrode;
a second power source configured to generate a discharge between the cathode electrode and the anode electrode;
a third power source configured to generate a potential difference between the cathode electrode or the anode electrode and the substrate;
an ionization area configured to ionize the gas to generate an ionized gas by the discharge; and
an acceleration area in which the ionized gas is accelerated by the potential difference, wherein
a soft-magnetic cylinder is provided around the acceleration area.

[2] The film forming device according to [1], wherein
the soft-magnetic cylinder has a saturation magnetic-flux density of 0.5 T or more.

[3] The film forming device according to [1] or [2], wherein
the soft-magnetic cylinder has a coercivity of 0.5 A/m or less.

[4] The film forming device according to any one of [1] to [3], wherein
the soft-magnetic cylinder is made of an amorphous metal containing one or more elements selected from a group consisting of Co, Fe, and Ni.

[5] A method for forming a carbon film on a surface of a substrate, the method using a film forming device including:
a film forming chamber;
a holder configured to hold a substrate in the film forming chamber;
an inlet pipe configured to introduce a gas of a raw material containing carbon into the film forming chamber;
a cathode electrode that is filamentous;
a first power source configured to heat the cathode electrode by energization;
an anode electrode provided around the cathode electrode;
a second power source configured to generate a discharge between the cathode electrode and the anode electrode;
a third power source configured to generate a potential difference between the cathode electrode or the anode electrode and the substrate;
an ionization area configured to ionize the gas to generate an ionized gas by the discharge; and
an acceleration area in which the ionized gas is accelerated by the potential difference, wherein
the film forming device is provided with a soft-magnetic cylinder provided around the acceleration area, the method comprising:
introducing the gas into the film forming chamber from the inlet pipe;
ionizing the gas by the discharge between the cathode electrode that is filamentous and heated by energization and the anode electrode provided around the cathode electrode; and
emitting the ionized gas toward the surface of the substrate by accelerating the ionized gas inside the acceleration area.

### BRIEF DESCRIPTION OF THE DRAWINGS

FIG. 1 is a schematic structural diagram schematically illustrating a film forming device according to an embodiment of the present disclosure;

FIG. 2 is a cross-sectional view illustrating an example of a magnetic recording medium manufactured by applying the film forming device according to the embodiment of the present disclosure;

FIG. 3 is a perspective view illustrating an example of a magnetic recording and reproducing device;

FIG. 4 is a plan view illustrating a configuration of an in-line film forming device to which the film forming device according to the embodiment of the present disclosure is applied;

FIG. 5 is a side view illustrating carriers of an in-line film forming device to which the film forming device according to the embodiment of the present disclosure is applied; and

FIG. 6 is an enlarged side view of the carrier as illustrated in FIG. 5.

### DETAILED DESCRIPTION OF THE DISCLOSURE

Demand for enhancement of recording density of magnetic recording media continues, and a film forming device and a method for forming a carbon film which can further smooth a protective film are required.

The present disclosure has been made in view of the above circumstances, and an object of the present disclosure is to provide a film forming device and a method for forming a carbon film which can stabilize the thickness distribution of the carbon film.

An embodiment of the present disclosure will now be described in detail with reference to the drawings. In the drawings used in the following description, the characteristic parts are enlarged for convenience, and dimensional proportions of components are not necessarily the same as in reality. In this specification, “to” indicating a numerical range means that the numerical values described before and after it are included as the lower limit and upper limit, unless otherwise specified. In the numerical range represented by “to”, when only the upper limit is indicated in units, the lower limit is indicated in the same units.

### (Film Forming Device and Method for Forming Carbon Film)

The film forming device and the method for forming a carbon film according to the embodiment of the present disclosure will be described in the following. In the present embodiment, the film forming device according to the present embodiment is a carbon-film forming device for forming a carbon film as the protective film.

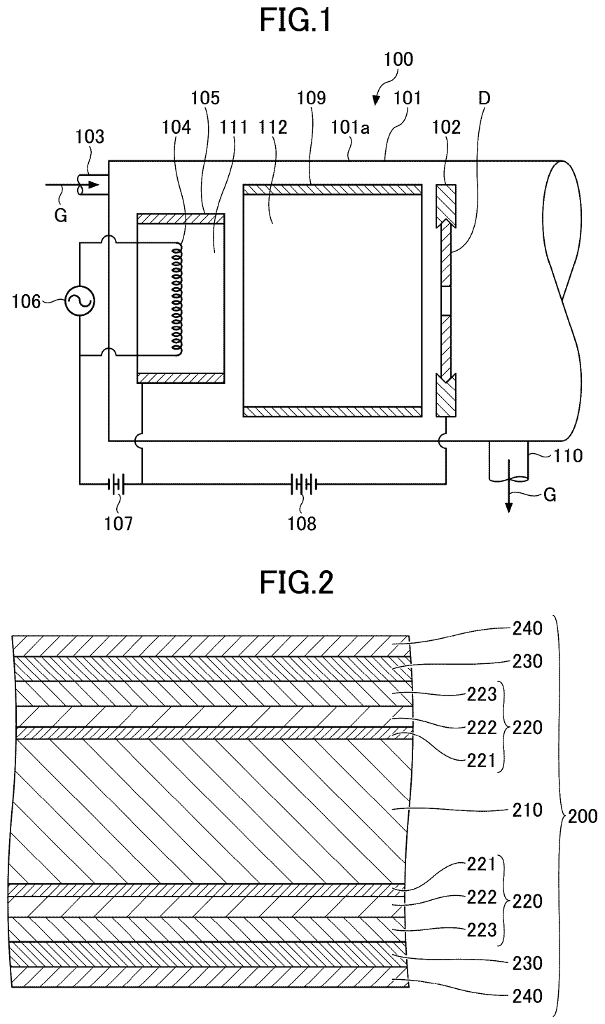

FIG. 1 is a schematic structural diagram schematically illustrating the film forming device according to the present embodiment. As illustrated in FIG. 1, a film forming device 100 is a film forming device that uses an ion-beam deposition method. The film forming device 100 includes a film forming chamber 101, a holder 102 for holding a substrate D in the film forming chamber 101, an inlet pipe 103 for introducing a gas G of a carbon-containing raw material into the film forming chamber 101, a filamentous cathode electrode 104 arranged in the film forming chamber 101, and an anode electrode 105 arranged around the cathode electrode 104 in the film forming chamber 101. The film forming device 100 includes a first power source 106 for heating the cathode electrode 104 by energization, a second power source 107 for generating a discharge between the cathode electrode 104 and the anode electrode 105, and a third power source 108 for providing a potential difference between the cathode electrode 104 or the anode electrode 105 and the substrate D. Furthermore, the film forming device 100 includes an ionization area 111 for ionizing a gas by the discharge, an acceleration area 112 for accelerating the ionized gas by the potential difference, and a soft-magnetic cylinder 109 provided around the acceleration area 112.

The term “gas G of the carbon-containing raw material” means that the carbon-containing raw material is a gas, and is a raw-material gas obtained by gasifying the carbon-containing raw material.

The film forming chamber 101 is air-tight with a chamber wall 101a, and is configured such that the inside can be evacuated under reduced pressure through an exhaust pipe 110 connected to a vacuum pump (not illustrated).

The first power source 106 is an AC power source connected to the cathode electrode 104, and supplies power to the cathode electrode 104 when forming a carbon film. The first power source 106 is not limited to the AC power source, and may be a DC power source.

The second power source 107 is a DC power source connected to the cathode electrode 104 on a negative electrode side and to the anode electrode 105 on a positive electrode side, and causes a discharge between the cathode electrode 104 and the anode electrode 105 when forming a carbon film.

The third power source 108 is a DC power source in which the positive electrode side is connected to the anode electrode 105 and the negative electrode side is connected to the holder 102, and imparts a potential difference between the anode electrode 105 and the substrate D held by the holder 102 when forming a carbon film. The third power source 108 may have a configuration in which the positive electrode side is connected to the cathode electrode 104.

In the film forming chamber 101, the ionization area 111 in which gas is ionized by a discharge and the acceleration area 112 in which the ionized gas is accelerated by a potential difference are formed. The soft-magnetic cylinder 109 is provided around the acceleration area 112.

According to an examination by the inventors of the present disclosure, it was noticed that in an existing film forming device, no drastic measures were taken against magnetic influences such as an external leakage magnetic field, and that this was a factor that made the film thickness distribution of the carbon film unstable. That is, there are often magnets for a magnetron of a sputtering device or magnets used for a transfer unit of a processing substrate around the film forming device, and the leakage magnetic field from these magnets adversely affects the film forming device. The inventors of the present disclosure found that when the soft-magnetic cylinder 109 is provided around the acceleration area 112, the film thickness distribution of the carbon film to be formed can be stabilized.

In the present embodiment, by providing the soft-magnetic cylinder 109 around the acceleration area 112, paths of ions accelerated in a direction of the substrate D (right direction in FIG. 1) are prevented from being disturbed by the leakage magnetic field, and a carbon film having a substantially uniform film thickness can be formed on one surface of the substrate D (film formation surface).

The soft-magnetic cylinder 109 is preferably rotationally symmetric about a central axis perpendicular to the film formation surface of the substrate D. In this manner, the acceleration area 112 can be rotationally symmetric about the film formation surface of the substrate D, such that the film thickness distribution of the carbon film on the film formation surface can be made more uniform.

The soft-magnetic cylinder 109 is preferably in an electrically floating state (floating potential). In this way, the potential distribution in the soft-magnetic cylinder 109 becomes more uniform, and the paths of the ions accelerated in the soft-magnetic cylinder 109 become more stable and perpendicular to the film formation surface of the substrate D.

A saturation magnetic-flux density Bs of the soft-magnetic cylinder 109 is 0.5 Tesla (T) or more and preferably as high as possible. Accordingly, the influence of the leakage magnetic field in the soft-magnetic cylinder 109 can be further reduced.

A coercivity Hc of the soft-magnetic cylinder 109 is preferably 0.5 Ampere per meter (A/m) or less and as low as possible. In this manner, it is possible to suppress magnetization of the soft-magnetic cylinder 109 by the leakage magnetic field, and thus, influence of the magnetic field in the soft-magnetic cylinder 109 can be further reduced.

The soft-magnetic cylinder 109 is preferably an amorphous metal containing one or more elements selected from a group consisting of Co, Fe, and Ni. In this manner, the influence of the leakage magnetic field in the soft-magnetic cylinder 109 can be further reduced, and magnetization of the soft-magnetic cylinder 109 by the leakage magnetic field can be further suppressed.

In the film forming device 100, when a carbon film is formed on the substrate D, the voltage and current of the first power source 106, the second power source 107, and the third power source 108 may be appropriately set according to the size of the substrate D. When the substrate D is, for example, a disk-shaped substrate having an outer diameter of 3.5 inches, the voltage of the first power source 106 is preferably set within a range from 10 to 100 V and the current is preferably set within a range from 5 to 50 A in direct current or alternating current. The voltage of the second power source 107 is preferably set within a range from 50 to 300 V and the current is preferably set within a range from 10 to 5000 mA. The voltage of the third power source 108 is preferably set within a range from 30 to 500 V and the current is preferably set within a range from 10 to 200 mA.

When a carbon film is formed on the surface of the substrate D by using the film forming device 100 having the above-described configuration, the gas G of the carbon-containing raw material is introduced into the film forming chamber 101 which has been reduced in pressure through the exhaust pipe 110 through the inlet pipe 103. The raw-material gas G is excited and decomposed into ionized gas (carbon ions) by thermal plasma of the cathode electrode 104 heated by the supply of electric power from the first power source 106 and plasma in the ionization area 111 generated by the discharge between the cathode electrode 104 and the anode electrode 105 connected to the second power source 107. The carbon ions excited by the plasma in the ionization area 111 collide with the surface of the substrate D while accelerating in the acceleration area 112 toward the substrate D which is set to a negative potential by the third power source 108.

In the method for forming a carbon film by using the film forming device 100, for example, a hydrocarbon gas can be used as the gas G of the carbon-containing raw material. As the hydrocarbon, it is preferable to use one or more low-carbon hydrocarbons selected from a group consisting of lower saturated hydrocarbons, lower unsaturated hydrocarbons, and lower cyclic hydrocarbons. In this case, “low carbon” means that the number of contained carbons is within a range from 1 to 10.

As the lower saturated hydrocarbon, methane, ethane, propane, butane, octane, and the like can be used.

As the lower unsaturated hydrocarbon, isoprene, ethylene, propylene, butylene, butadiene, and the like can be used.

As the lower cyclic hydrocarbon, benzene, toluene, xylene, styrene, naphthalene, cyclohexane, cyclohexadiene, and the like can be used.

The reason why it is preferable to use the lower hydrocarbons is that, when the number of carbons in the hydrocarbon exceeds the range specified above, it becomes difficult to supply the hydrocarbon as the gas from the inlet pipe 103, decomposition of the hydrocarbon during discharge becomes difficult, and a generated carbon film thus contains a large amount of polymer components which are inferior in strength.

In order to induce generation of the plasma in the film forming chamber 101, it is preferable to use a mixture gas, which is the gas obtained by mixing inert gas, hydrogen gas, and the like with the gas G of the carbon-containing raw material. A mixing ratio of the hydrocarbon and the inert gas in the mixture gas is, in a ratio of the hydrocarbon to the inert gas, preferably set within a range from 2:1 to 1:100 (volume ratio). In this way, a carbon film with high hardness and high durability can be formed.

In the film forming device 100, a carbon film is formed only on one surface (one side) of the substrate D, but it may be formed on both surfaces (both sides) of the substrate D. In this case, the same device configuration as in the case where a carbon film is formed only on one surface of the substrate D may be arranged on both sides of the substrate D in the film forming chamber 101.

### (Method of Manufacturing Magnetic Recording Medium)

Next, a method of manufacturing a magnetic recording medium by applying the film forming device 100 will be described. In the present embodiment, a case of manufacturing a magnetic recording medium to be mounted on a hard disk device will be described by using an in-line film forming device in which film-forming processes are performed while substrates on which a carbon film is to be formed are sequentially conveyed between a plurality of film forming chambers.

### (Magnetic Recording Medium)

As illustrated in FIG. 2, for example, a magnetic recording medium 200 manufactured by using the film forming device 100 has a structure in which a magnetic layer 220, a protective layer 230, and a lubricant film 240 are stacked in order on both surfaces of a non-magnetic substrate 210. The magnetic layer 220 includes a soft-magnetic layer 221, an intermediate layer 222, and a recording magnetic layer 223, and has a stacking structure where the layers are stacked in this order from a side of the non-magnetic substrate 210.

In the magnetic recording medium 200, a carbon film with high hardness and high density is formed with a uniform thickness as the protective layer 230 by using the film forming device 100. In this case, the thickness of the carbon film in the magnetic recording medium 200 can be made thin, for example, the thickness of the carbon film can be made about 2 nm or less.

Therefore, since a distance between the magnetic recording medium 200 and the magnetic head can be shortened through use of the film forming device 100, a recording density of the magnetic recording medium 200 can be enhanced and the corrosion resistance of the magnetic recording medium 200 can be enhanced.

Each layer of the magnetic recording medium 200 other than the protective layer 230 will be described in the following.

As the non-magnetic substrate 210, any non-magnetic substrate, for example, a substrate including an Al alloy formed mainly of Al such as an Al—Mg alloy and the like, an ordinary soda glass, an aluminosilicate glass, a crystallized glass, silicon, titanium, ceramics, and various resins can be used. Among these, it is preferable to use an Al alloy substrate made of an Al alloy, a glass substrate made of crystallized glass, or a silicon substrate made of silicon. An average surface roughness (Ra) in each of these substrates is preferably 1 nm or less, more preferably 0.5 nm or less, and more preferably 0.1 nm or less.

The magnetic layer 220 may be an in-plane magnetic layer for an in-plane magnetic recording medium or a perpendicular magnetic layer for a perpendicular magnetic recording medium, but it is preferable to use the perpendicular magnetic layer in order to realize a higher recording density. The magnetic layer 220 is preferably formed of an alloy mainly formed of Co. For example, as the magnetic layer 220 for the perpendicular magnetic recording medium, for example, a laminate of the soft-magnetic layer 221 made of a soft-magnetic FeCo alloy (FeCoB, FeCoSiB, FeCoZr, FeCoZrB, FeCoZrBCu, etc.), a FeTa alloy (FeTaN, FeTaC, etc.), or a Co alloy (CoTaZr, CoZrNB, CoB, etc.), the intermediate layer 222 made of Ru or the like, and the recording magnetic layer 223 made of 60Co-15Cr-15 Pt alloy or 70Co-5Cr-15 Pt-10SiO₂ alloy can be used.

The overall thickness of the magnetic layer 220 is within a range from 3 to 20 nm, preferably within a range from 5 to 15 nm, and the magnetic layer 220 may be formed to obtain sufficient head input and output according to the type of magnetic alloy to be used and the stacking structure. For the thickness of the magnetic layer 220, although it is necessary to have a certain thickness of the magnetic layer in order to obtain a certain level of output during reproduction, because parameters representing recording and reproduction characteristics usually deteriorate as the output increases, it is necessary to set an optimum film thickness.

As a lubricant used for the lubricant film 240, a fluorinated liquid lubricant such as perfluoroether (PFPE), or a solid lubricant such as a fatty acid can be used. The lubricant film 240 is usually formed with a thickness within a range from 1 to 4 nm. As a lubricant coating method, a conventionally known general coating method, such as a dipping method or a spin coating method, can be used.

### (Magnetic Recording and Reproducing Device)

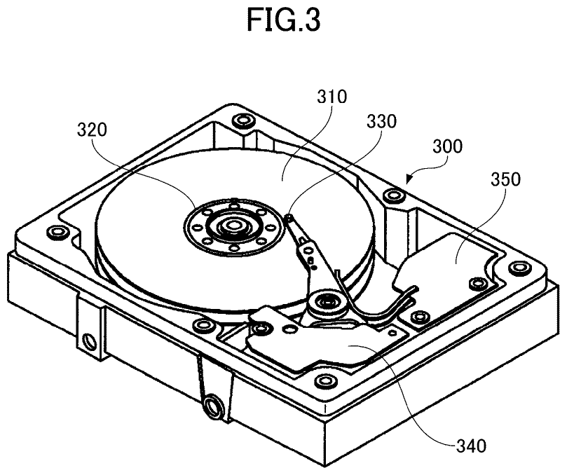

As a magnetic recording and reproducing device using the magnetic recording medium 200, a hard disk device can be cited, for example. As illustrated in FIG. 3, a hard disk device 300 includes a magnetic disk 310 formed of the magnetic recording medium 200 (see FIG. 2), a medium driver 320 for rotating and driving the magnetic disk 310, a magnetic head 330 for recording and reproducing information on the magnetic disk 310, a head driver 340, and a recording-and-reproducing signal processing system 350. The recording-and-reproducing signal processing system 350 processes input data, sends a recording signal to the magnetic head 330, and processes a reproduction signal from the magnetic head 330 to output data.

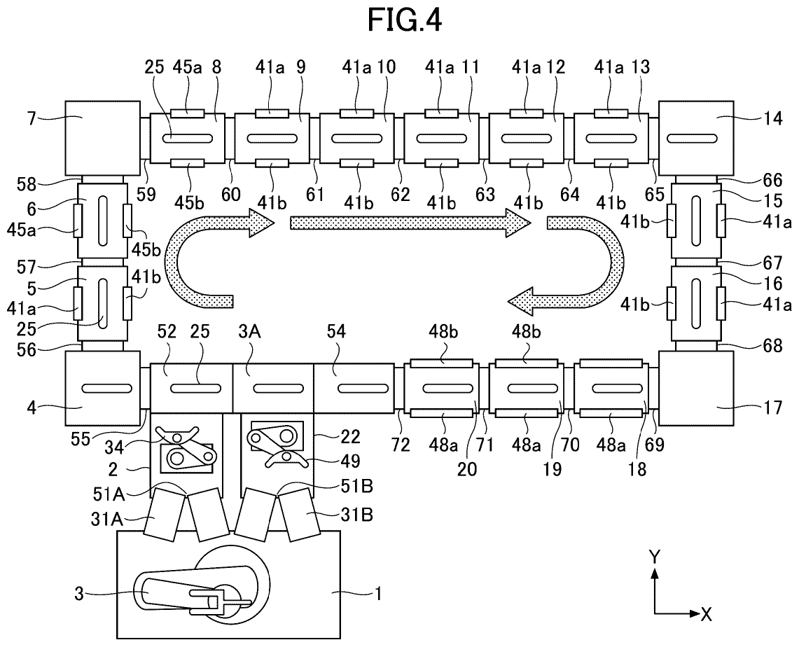

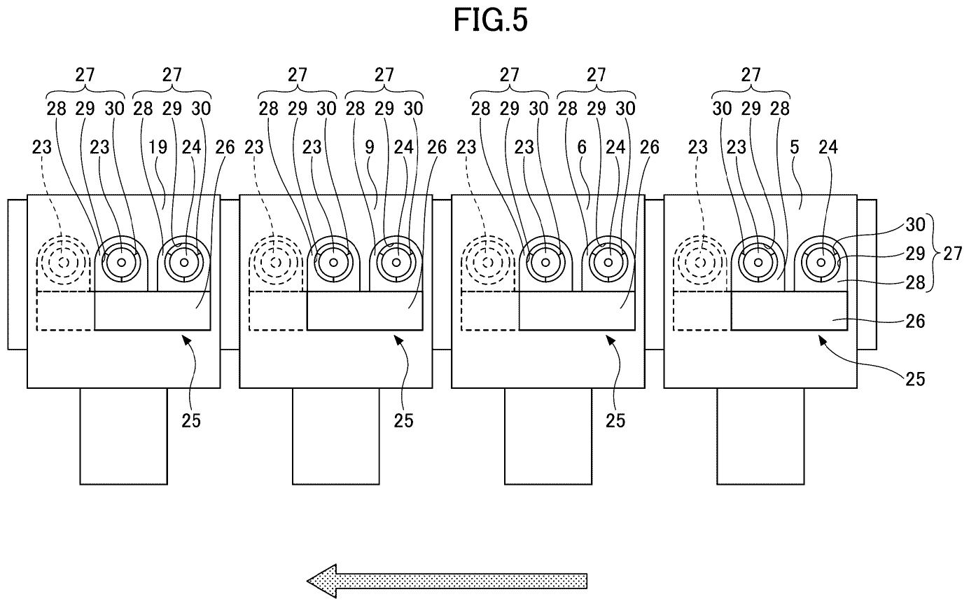

(In-Line Film Forming Device) In manufacturing the magnetic recording medium 200, an in-line film forming device (manufacturing device for magnetic recording medium) as illustrated in FIG. 4, for example, to which the film forming device 100 is applied is used. By using the in-line film forming device as illustrated in FIG. 4, the magnetic layer 220 including at least the soft-magnetic layer 221, the intermediate layer 222, and the recording magnetic layer 223, the protective layer 230, and the lubricant film 240 are successively laminated on both surfaces of the non-magnetic substrate 210, which is the target of the film formation, and thus, the above-mentioned magnetic recording medium 200 having a high hardness and dense carbon film as the protective layer 230 can be stably manufactured.

Specifically, the above-mentioned in-line film forming device includes a stand for a cassette-substrate transfer robot (robot stand) 1, a substrate-supply robot chamber 2 adjacent to the robot stand 1, a cassette-substrate transfer robot 3 arranged on the robot stand 1, a substrate-supply robot 34 arranged in the substrate-supply robot chamber 2, and a substrate mounting chamber 52 adjacent to the substrate-supply robot chamber 2. Furthermore, the above-mentioned in-line film forming device includes corner chambers 4, 7, 14, and 17 for rotating a carrier 25, processing chambers 5, 6, 8 to 13, 15, 16, and 18 to 20 arranged between the corresponding corner chambers 4, 7, 14, and 17, a substrate removal chamber 54 arranged adjacent to the processing chamber 20, and an ashing chamber 3A arranged between the substrate mounting chamber 52 and the substrate removal chamber 54. The above-mentioned in-line film forming device includes a substrate-removal robot chamber 22 arranged adjacent to the ashing chamber 3A, a substrate-removal robot 49 arranged in the substrate-removal robot chamber 22, and a plurality of carriers 25 conveyed through each of these chambers 2, 3A, 4 to 20, 52, and 54.

The term “chamber” means any one of the substrate-supply robot chamber 2, the ashing chamber 3A, the corner chambers 4, 7, 14, and 17, the processing chambers 5, 6, 8 to 13, 15, 16, and 18 to 20, the substrate mounting chamber 52, and the substrate removal chamber 54.

Each of the chambers 2, 3A, 4 to 20, 52, and 54 is connected to two adjacent walls, and gate valves 55 to 72 are provided at the corresponding connection portion of the chambers 2, 3A, 4 to 20, 52, and 54. When the gate valves 55 to 72 are closed, each of the chambers 2, 3A, 4 to 20, 52, and 54 becomes an independent enclosed space.

A vacuum pump (not illustrated) is connected to each of the chambers 2, 3A, 4 to 20, 52, and 54. The magnetic recording medium 200 as illustrated in FIG. 2 is finally obtained by successively forming the magnetic layer 220 (the soft-magnetic layer 221, the intermediate layer 222, and the recording magnetic layer 223) and the protective layer 230 on both surfaces of the non-magnetic substrate 210 (see FIG. 2) mounted on the carrier 25 in the chambers 2, 3A, 4 to 20, 52, and 54, while the carrier 25 is successively conveyed by a conveying mechanism (not illustrated) into each of the chambers 2, 3A, 4 to 20, 52, and 54, which are reduced in pressure by the operation of the vacuum pumps.

Among the chambers 2, 3A, 4 to 20, 52, and 54, the corner chambers 4, 7, 14, and 17 are chambers for changing a moving direction of the carrier 25, and a mechanism for rotating the carrier 25 to move it to the next film forming chamber is provided in the corner chambers 4, 7, 14, and 17.

The cassette-substrate transfer robot 3 supplies the non-magnetic substrate 210 to the substrate-supply robot chamber 2 from the cassette containing the non-magnetic substrate 210 before film formation. Additionally, the cassette-substrate transfer robot 3 retrieves the non-magnetic substrate 210 (magnetic recording medium 200) after film formation removed by the substrate-removal robot 49, from the substrate-removal robot chamber 22. The substrate-supply robot chamber 2 is provided, at one side wall of the chamber, with an opening 51A open to the outside and a gate valve 31A for opening and closing the opening 51A. The substrate-removal robot chamber 22 is provided, at one side wall of the chamber, with an opening 51B open to the outside and a gate valve 31B for opening and closing the opening 51B.

Inside the substrate mounting chamber 52, the non-magnetic substrate 210 before film formation is mounted on the carrier 25 by using the substrate-supply robot 34. Additionally, inside the substrate removal chamber 54, the non-magnetic substrate 210 (magnetic recording medium 200) after film formation mounted on the carrier 25 is removed by using the substrate-removal robot 49.

The ashing chamber 3A performs ashing of the carrier 25 conveyed from the substrate removal chamber 54, and then conveys the carrier 25 to the substrate mounting chamber 52.

Among the processing chambers 5, 6, 8 to 13, 15, 16, and 18 to 20, the processing chambers 5, 6, 8 to 13, 15, and 16 constitute a plurality of film forming chambers for forming the magnetic layer 220. These film forming chambers include mechanisms for forming the soft-magnetic layer 221, the intermediate layer 222, and the recording magnetic layer 223 on both sides of the non-magnetic substrate 210.

Furthermore, the processing chambers 18 to 20 constitute a plurality of film forming chambers for forming the protective layer 230. These film forming chambers have the same device configuration as the film forming device using the ion-beam deposition method as illustrated in FIG. 1, and form the dense carbon film with high hardness described above as the protective layer 230, on top of the magnetic layer 220 formed on both surfaces of the non-magnetic substrate 210.

Each of the processing chambers 5, 6, 8 to 13, 15, 16, and 18 to 20 includes two processors (a pair of processors 41a and 41b, a pair of processors 45a and 45b, or a pair of processors 48a and 48b), one on each of the two chamber sides facing the carrier 25. One of the pair of processors, that is, the processor 41a, 45a, or 48a performs film formation on the left side of the non-magnetic substrate 210 with respect to a traveling direction of the carrier 25, and the other of the pair of processors, that is, the processor 41b, 45b, or 48b performs film formation on the right side of the non-magnetic substrate 210 with respect to the traveling direction of the carrier 25.

Each of the processing chambers 5, 6, 8 to 13, 15, 16, and 18 to 20 is provided with a processing-gas supply pipe. The processing-gas supply pipe is provided with a valve whose opening and closing is controlled by a control mechanism (not illustrated). By opening and closing the valve of each processing-gas supply pipe and a pump gate valve, the supply of gas from the processing-gas supply pipe and the pressure and discharge of the gas in the chamber are controlled.

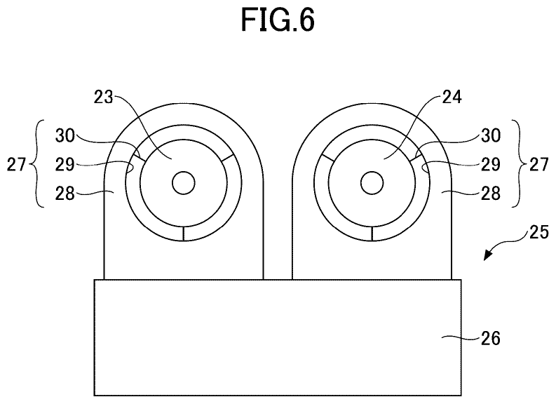

As illustrated in FIGS. 5 and 6, the carrier 25 includes a support base 26 and a plurality of substrate mounting portions 27 provided on an upper surface of the support base 26. In the present embodiment, since two substrate mounting portions 27 are mounted, two non-magnetic substrates 210 mounted on the substrate mounting portions 27 are hereinafter treated as a first film-formation substrate 23 and a second film-formation substrate 24, respectively.

The substrate mounting portion 27 includes a plate 28 having a thickness of about 1 to several times the thickness of the first film-formation substrate 23 and the second film-formation substrate 24, a circular through-hole 29 formed slightly larger in diameter than an outer periphery of the first film-formation substrate 23 and the second film-formation substrate 24, and a plurality of supports 30 projecting toward the inside of the through-hole 29 around the through-hole 29. In the substrate mounting portion 27, the through-hole 29 is formed in the plate 28, and a plurality of supports 30 projecting toward the inside of the through-hole 29 are provided on the periphery of the through-hole 29. In the substrate mounting portion 27, the first film-formation substrate 23 and the second film-formation substrate 24 are respectively fitted into the corresponding through-hole 29, and the supports 30 are engaged with an outer edge of the fitted substrate, such that the first film-formation substrate 23 and the second film-formation substrate 24 are held vertically (in a state where the main surfaces of each of the first film-formation substrate 23 and the second film-formation substrate 24 are parallel to a gravity direction). That is, the substrate mounting portion 27 is arranged on the upper surface of the support base 26 while being aligned with the other substrate mounting portion 27, such that the main surfaces of the first film-formation substrate 23 and the second film-formation substrate 24 mounted on the carrier 25 are substantially orthogonal to the upper surface of the support base 26, and the main surfaces of the first film-formation substrate 23 and the second film-formation substrate 24 are on the same plane.

Moreover, each of the above-described processing chambers 5, 6, 8 to 13, 15, 16, and 18 to 20 is provided with the two processors (the pair of processors 41a and 41b, the pair of processors 45a and 45b, or the pair of processors 48a and 48b in FIG. 4) one on each of the two chamber sides facing the carrier 25. In this case, for example, in a state where the carrier 25 is stopped at a first processing position indicated by a solid line in FIG. 5, film-forming processing is performed on the first film-formation substrate 23 on the left side of the carrier 25. Thereafter, the carrier 25 moves to a second processing position indicated by a dashed line in FIG. 5, and in a state where the carrier 25 is stopped at the second processing position, the film-forming processing is performed on the second film-formation substrate 24 on the right side of the carrier 25.

In a case where there are a total of four processors on two chamber sides facing the carrier 25, that is the pair of facing processors being respectively provided to face the main surfaces of each of the first film-formation substrate 23 and the second film-formation substrate 24, it is not necessary to move the carrier 25, and film-forming processing can be simultaneously performed on both the first film-formation substrate 23 and the second film-formation substrate 24 held by the carrier 25.

After the film formation, the first film-formation substrate 23 and the second film-formation substrate 24 are removed from the carrier 25, and only the carrier 25 on which a carbon film is formed is conveyed into the ashing chamber 3A as illustrated in FIG. 1. Then, oxygen gas is introduced from any part of the ashing chamber 3A, and oxygen plasma is generated in the ashing chamber 3A by using the oxygen gas. When the oxygen plasma contacts the carbon film formed on the surface of the carrier 25, the carbon film is decomposed into co or CO₂ gas and removed.

### EXAMPLES

Hereinafter, the present embodiment will be specifically described based on the Examples, but the present embodiment is not limited to these Examples.

### <Manufacturing of Magnetic Recording Medium>

### Example 1

In Example 1, an aluminum substrate on which NiP plating was applied was prepared as a non-magnetic substrate. Next, a magnetic layer was formed by successively laminating a soft-magnetic layer formed of FeCoB with a film thickness of 60 nm, an intermediate layer formed of Ru with a film thickness of 10 nm, and a recording magnetic layer formed of 70Co-5Cr-15 Pt-10SiO₂ alloy with a film thickness of 15 nm on both sides of the non-magnetic substrate mounted on an A5052 aluminum alloy carrier by using the in-line film forming device as illustrated in FIG. 4. Next, the non-magnetic substrate mounted on the carrier was transported to a processing chamber having the same device configuration as that of the film forming device as illustrated in FIG. 1, and a protective layer formed of a carbon film was formed on both sides of the non-magnetic substrate on which the magnetic layers were formed.

Specifically, the processing chamber of the carbon-film forming device had a cylindrical shape with an outer diameter of 180 mm and a length of 250 mm. The chamber wall constituting the processing chamber was made of SUS304. A coiled cathode electrode made of tantalum of about 30 mm in length and a cylindrical anode electrode surrounding the cathode electrode were provided in the processing chamber. The anode electrode was made of SUS304, with an outer diameter of 140 mm and a length of 40 mm. The distance between the cathode electrode and the non-magnetic substrate was 160 mm. A soft-magnetic cylinder was provided between the cathode electrode and the anode electrode and the non-magnetic substrate. The cylinder had a floating potential. The cylinder had an outer diameter of 150 mm and a length of 130 mm. The composition of the cylinder was amorphous 70Ni-10Co-10Fe-5Si-5B (at %). The saturation magnetic-flux density Bs was 0.6 T and the coercivity Hc was 0.2 A/m.

Gasified toluene was used as the raw-material gas. As for film-forming conditions of the carbon film, a gas flow rate was 2.2 SCCM (1 SCCM of Ar as the carrier gas), the reaction pressure was 0.2 Pa, the cathode voltage was 110 V, the voltage between the cathode electrode and the anode electrode was 75 V, the current was 1300 mA, the ion acceleration voltage was 100 V at 180 mA, the length of film formation time was 2 seconds, and the thickness of the carbon film to be formed was 1.5 nm.

### Examples 2 and 3 and Comparative Examples 1 to 3

A magnetic recording medium was manufactured under the same conditions as in Example 1, but the cylinder in the carbon-film forming device was changed to the contents as illustrated in Table 1. In Comparative Example 3, the cylinder was not provided, and a cylindrical magnet was provided outside the outer wall of the acceleration area of the carbon-film forming device. The magnet had a shape of 185 mm in inner diameter and 40 mm in length, and 20 NdFe-based sintered rod magnets of 10 mm square side lengths and 40 mm in length were arranged in parallel at equal intervals. The sintered rod magnets were arranged such that the S pole was on the substrate side and the N pole was on the cathode side. The total magnetic force of this magnet was 50 G (5 mT).

### <Evaluation of Magnetic Recording Media>

Corrosion tests were performed on the magnetic recording media of each Example and Comparative Example.

### (Corrosion Test)

In the corrosion test, after the magnetic recording media was left at 90° C. and 90% humidity for 96 hours, the amounts of Co elution on the outer-peripheral, center-peripheral, and inner-peripheral surfaces of the magnetic recording media were measured. When the carbon film thickness of the magnetic recording media is uneven, Co contained in the magnetic layer elutes to the surface due to corrosion. Therefore, the unevenness of the carbon film thickness can be evaluated by measuring the amount of Co elution on the surface of the magnetic recording medium. In the evaluation, the larger the amount of Co elution, the more uneven the carbon film thickness. The measurement results are as illustrated in Table 1.

TABLE 1

| | | | | | Co ELUTION AMOUNT [μg/m²] | | |
|---|---|---|---|---|---|---|---|
| | CYLINDER | | | | INNER- | CENTER- | OUTER- |
| | | | Bs | Hc | PERIPHERAL | PERIPHERAL | PERIPHERAL |
| | MATERIAL [at %] | CHARACTERISTICS | [T] | [A/m] | SURFACE | SURFACE | SURFACE |
| EXAMPLE 1 | 70Ni—10Co—10Fe—5Si—5B | SOFT-MAGNETIC, | 0.6 | 0.2 | 0.2 | 0.5 | 1.0 |
| | | AMORPHOUS | | | | | |
| EXAMPLE 2 | 78Ni—12Fe | SOFT-MAGNETIC, | 0.7 | 1.0 | 0.25 | 0.7 | 1.5 |
| | | POLYCRYSTALLINE | | | | | |
| EXAMPLE 3 | SUS430 | SOFT-MAGNETIC, | 1.1 | 2.4 | 0.3 | 0.8 | 1.8 |
| | (83Fe—17Cr) | POLYCRYSTALLINE | | | | | |
| COMPARATIVE | ALUMINUM | NON-MAGNETIC, | 0 | 0 | 0.3 | 1.0 | 2.0 |
| EXAMPLE 1 | | POLYCRYSTALLINE | | | | | |
| COMPARATIVE | SUS304 | NON-MAGNETIC, | 0 | 0 | 0.3 | 1.0 | 2.0 |
| EXAMPLE 2 | (74Fe—18Cr—8Ni) | POLYCRYSTALLINE | | | | | |

| | | | | |
|---|---|---|---|---|
| COMPARATIVE | NOT PROVIDED, (APPLIED MAGNETIC | 0.3 | 0.9 | 1.9 |
| EXAMPLE 3 | FIELD EXTERNALLY) | | | |

According to Table 1, the outer-peripheral, center-peripheral, and inner-peripheral surfaces of the magnetic recording medium in each example had an overall smaller amount of Co elution than the outer-peripheral, center-peripheral, and inner-peripheral surfaces of the magnetic recording medium of each comparative example. Therefore, it can be said that the carbon films of the magnetic recording media of the examples have a more uniform film thickness than the carbon films of the magnetic recording media of the comparative examples.

Therefore, it can be said that the film thickness distribution of the carbon film can be stabilized by forming the carbon film as the protective layer on both sides of the non-magnetic substrate on which the magnetic layer is respectively formed, by using the film forming device of the present embodiment. Since the film thickness of the carbon film can be made thin by using the film forming device of the present embodiment, the distance between the magnetic recording medium and the magnetic head can be shortened, and thus, a magnetic recording medium with high recording density can be obtained.

According to the present disclosure, the thickness distribution of a carbon film can be stabilized. When an obtained carbon film is used as a protective film of a magnetic recording medium or the like, the thickness of the carbon film can be reduced, such that the distance between the magnetic recording medium and the magnetic head can be shortened. As a result, the recording density of the magnetic recording medium can be enhanced.

What is claimed is:

1. A film forming device, comprising:
a film forming chamber;
a holder configured to hold a substrate in the film forming chamber;
an inlet pipe configured to introduce a gas of a raw material containing carbon into the film forming chamber;
a cathode electrode that is filamentous;
a first power source configured to heat the cathode electrode by energization;
an anode electrode provided around the cathode electrode;
a second power source configured to generate a discharge between the cathode electrode and the anode electrode;
a third power source configured to generate a potential difference between the cathode electrode or the anode electrode and the substrate;
an ionization area configured to ionize the gas to generate an ionized gas by the discharge; and
an acceleration area in which the ionized gas is accelerated by the potential difference, wherein
a soft-magnetic cylinder is provided around the acceleration area.

2. The film forming device according to claim 1, wherein
the soft-magnetic cylinder has a saturation magnetic-flux density of 0.5 T or more.

3. The film forming device according to claim 1, wherein
the soft-magnetic cylinder has a coercivity of 0.5 A/m or less.

4. The film forming device according to claim 1, wherein
the soft-magnetic cylinder is made of an amorphous metal containing one or more elements selected from a group consisting of Co, Fe, and Ni.

5. A method for forming a carbon film on a surface of a substrate, the method using a film forming device including:
a film forming chamber;
a holder configured to hold a substrate in the film forming chamber;
an inlet pipe configured to introduce a gas of a raw material containing carbon into the film forming chamber;
a cathode electrode that is filamentous;
a first power source configured to heat the cathode electrode by energization;
an anode electrode provided around the cathode electrode;
a second power source configured to generate a discharge between the cathode electrode and the anode electrode;
a third power source configured to generate a potential difference between the cathode electrode or the anode electrode and the substrate;
an ionization area configured to ionize the gas to generate an ionized gas by the discharge; and
an acceleration area in which the ionized gas is accelerated by the potential difference, wherein
the film forming device is provided with a soft-magnetic cylinder provided around the acceleration area, the method comprising:
introducing the gas into the film forming chamber from the inlet pipe;
ionizing the gas by the discharge between the cathode electrode that is filamentous and heated by energization and the anode electrode provided around the cathode electrode; and
emitting the ionized gas toward the surface of the substrate by accelerating the ionized gas inside the acceleration area.
